(19) United States
(12) Patent Application Publication
(10) Pub. No.: US 2022/0045267 A1
(43) Pub. Date: Feb. 10, 2022

(54) MAGNETORESISTIVE ELEMENT HAVING A SIDEWALL-CURRENT-CHANNEL STRUCTURE

(71) Applicants: YIMIN GUO, San Jose, CA (US); Rongfu Xiao, Dublin, CA (US); Jun Chen, Fremont, CA (US)

(72) Inventors: YIMIN GUO, San Jose, CA (US); Rongfu Xiao, Dublin, CA (US); Jun Chen, Fremont, CA (US)

(21) Appl. No.: 17/492,645

(22) Filed: Oct. 3, 2021

(51) Int. Cl. H01L 43/02; H01L 27/22; H01L 43/10; H01L 43/12

(52) U.S. Cl. CPC H01L 43/02; H01L 43/12; H01L 43/10; H01L 27/222

(57) ABSTRACT

A magnetoresistive element comprises a nonmagnetic sidewall-current-channel (SCC) structure provided on a surface of the magnetic recording layer, which is opposite to a surface of the magnetic recording layer where the tunnel barrier layer is provided, and comprising an insulating medium in a central region of the SCC structure, and a conductive medium being a sidewall of the SCC structure and surrounding the insulating medium, making an electric current crowding inside the magnetic recording layer to achieve a higher spin-polarization degree for an applied electric current.

### BACKGROUND OF THE INVENTION

### 1. Field of the Invention

This invention relates to the field of magnetoresistive elements. More specifically, the invention comprises perpendicular spin-transfer-torque magnetic-random-access memory (MRAM) using magnetoresistive elements as basic memory cells which potentially replace the conventional semiconductor memory used in electronic chips, especially mobile chips for power saving and non-volatility as well as memory blocks in processor-in-memory (PIM).

### 2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer, and a fixed reference layer that is located on the opposite side from the recording layer and maintains a predetermined magnetization direction.

As a write method to be used in such magnetoresistive elements, there has been suggested a write method (spin torque transfer switching technique) using spin momentum transfers. According to this method, the magnetization direction of a recording layer is reversed by applying a spin-polarized current along a specific direction to the magnetoresistive element. Furthermore, as the volume of the magnetic layer forming the recording layer is smaller, the injected spin-polarized current to write or switch can be also smaller. Accordingly, this method is expected to be a write method that can achieve both device miniaturization and lower currents. However, since the magnetization direction of the recording layer in the planar-type MTJ is in the film plane, a high shape anisotropy or high magneto-crystalline anisotropy material need be used in order to keep a relatively high energy barrier to resist thermal fluctuation. Since the high shape anisotropy requires a high aspect ratio, it is clearly undesirable due to the fact it prevents scalability and high density memory. There is a one technique proposed by J. Wang (see U.S. Pat. No. 7,981,697) that a composite recording layer comprises high magneto-crystalline anisotropy materials in a tri-layered exchange-spring structure: a first magnetic layer/a magnetic nano-current-channel (NCC) layer/a second magnetic layer, and local magnetic moments in the magnetic NCC layer switch the state of the memory element in reversal modes of exchange-spring magnets, which leads to a reduced switching current without scarifying the device thermal stability.

Further, as in a so-called perpendicular MTJ element, both two magnetization films have easy axis of magnetization in a direction perpendicular to the film plane due to their strong perpendicular magnetic anisotropy induced by both interface interaction and crystalline structure (shape anisotropies are not used), and accordingly, the device shape can be made smaller than that of an in-plane magnetization type. Also, variance in the easy axis of magnetization can be made smaller. Accordingly, by using a material having a large perpendicular magnetic anisotropy, both miniaturization and lower currents can be expected to be achieved while a thermal disturbance resistance is maintained or the thermal stability factor, E_{b}/k_{B}T (E_{b} being the energy barrier between the two stable states of an MTJ cell, k_{B} the Boltzmann constant, and T the absolute temperature), is maintained at a high value.

There has been a known technique for achieving a high MR ratio in a perpendicular MTJ element by forming an underneath MgO tunnel barrier layer and an MgO cap layer that sandwich a magnetic recording layer having a pair of amorphous CoFeB ferromagnetic layers and a Boron-absorbing layer positioned between them, and accelerate crystallization of the amorphous ferromagnetic film to match interfacial grain structure to MgO layers through a thermal annealing process. The magnetic recording layer crystallization starts from both the tunnel barrier layer side and the cap layer side to its center and forms a CoFe grain structure having a perpendicular magnetic anisotropy, as Boron elements migrate into the Boron-absorbing layer. Accordingly, a coherent perpendicular magnetic tunneling junction structure is formed. By using this technique, a high MR ratio can be achieved.

However, when an MTJ CD size is reduced to meet needs of very advanced and small-dimension technology nodes, both the MgO tunnel barrier layer and the MgO cap layer need to be thinner to keep a reasonable MTJ resistance. Note that the resistance property of layered materials is normally described by a resistance-area product (RA), which is product of resistance and area of a film layer. Therefore, it becomes more difficult to achieve both a high perpendicular magnetic anisotropy in a magnetic recording layer and a high MR ratio in an MTJ element in order to maintain a good thermal stability and read/write performance. A thick Boron-absorbing layer may help improve the perpendicular magnetic anisotropy in the recording layer. But, the damping constant of the recording layer may also increase from the thick Boron-absorbing layer material diffusion during the heat treatment in the device manufacturing process. At the same time, the CoFeB material in a magnetic recording layer has to be thin enough (normally between 1.0 nm and 2.0 nm) so that its magnetization is thermally stable in both perpendicular directions due to the limited value of its perpendicular magnetic anisotropy. Such a thin CoFeB material would be not capable to provide the highest spin polarization degree and the highest MR ratio which could be possibly achieved for a thick CoFeB material used in a planar MTJ element, thus limiting its potential for applications that need ultra-fast read speeds.

In a spin-injection perpendicular MRAM (or perpendicular spin-transfer-torque MRAM, i.e., pSTT-MRAM), a write current is proportional to both the damping constant and the energy barrier, and inversely proportional to a spin polarization degree. In general, the higher the write current, the faster the write process will complete. Ideally, a write process time of a few nano-seconds is required for high performance memories. However, a high write current of several hundred μA is typically required to flip that magnetization which is a major challenge for the establishment of pSTT-based storage devices in universal memories. But higher write current may accelerate the wear-out of the MTJ—particularly for perpendicular spin-transfer torque magnetic random-access memory (pSTT-MRAM), where the write current goes through the MTJ. Therefore, it is desired to develop new technologies to greatly enhance write efficiency or perpendicular spin-torque transfer efficiency while keeping a high MR ratio and thermal stability. A modeling study (see Article: Appl. Phys. Lett. 99, 132502 (2011), by I. Yulaev, et al.) on spin-transfer-torque magnetization reversal in a composite recording layer comprising a bi-layered exchange-spring structure: a magnetically soft layer/a magnetically hard layer, suggests that a reduction in critical write current may be expected from the increased perpendicular spin-torque transfer efficiency with reversal modes of exchange-spring magnets of the magnetically soft-hard composite structure.

There is a very different technique proposed by T. Suzuki, et al., (see Article: “Low-current domain wall motion MRAM with perpendicularly magnetized CoFeB/MgO magnetic tunnel junction and underlying hard magnets,” 2013 Symposium on VLSI Technology, pp. T138-T139) that utilizes magnetic domain wall (DW) motion with a perpendicularly magnetized CoFeB free layer and underlying hard magnets may lead to a low write current. In this structure, the magnetic domain wall moves or propagates by applying a spin-polarized current along a specific direction in the free layer film plane. Further, the magnetization switching behavior of perpendicularly magnetized CoFeB based free layers has been investigated by T. Devolder, et al., (see Article: “Material developments and domain wall based nanosecond-scale switching process in perpendicularly magnetized STT-MRAM cells,” IEEE Transactions on Magnetics, vol. 54, no. 2, pp. 1-9, 2018), and it has been discovered that the perpendicular magnetization reversal proceeds by a domain wall sweeping though the device at a few 10 nm per ns, and the switching time is roughly proportional to the device diameter, which may enable a fast write speed of a few ns. However, such a magnetic domain wall (DW) motion driven pSTT-MRAM has a complicated three-terminal structure which leads a low density and a high manufacturing cost.

### BRIEF SUMMARY OF THE PRESENT INVENTION

The present invention comprises perpendicular magnetoresistive elements having a sidewall-current-channel (SCC) structure and methods of manufacturing such perpendicular magnetoresistive elements for perpendicular spin-transfer-torque MRAM.

The perpendicular magnetoresistive element in the invention is sandwiched between an upper electrode and a lower electrode of each MRAM memory cell, which also comprises a write circuit which bi-directionally supplies a spin polarized current to the magnetoresistive element and a select transistor electrically connected between the magnetoresistive element and the write circuit.

The perpendicular magnetoresistive element comprises: a bottom electrode; an MTJ stack provided on a top surface of the bottom electrode and comprising: a magnetic reference layer having magnetic anisotropy in a direction perpendicular to a film surface and having an invariable magnetization direction, a tunnel barrier layer provided on a top surface of the magnetic reference layer and a magnetic recording layer provided on a top surface of the tunnel barrier layer and having magnetic anisotropy in a direction perpendicular to a film surface and having a variable magnetization direction; a sidewall-current-channel (SCC) structure provided on a top surface of the MTJ stack; a protective cap layer provided on a top surface of the SCC structure and a hard mask layer provided on a top surface of the protective cap layer, wherein the SCC structure comprises an insulating medium throughout the SCC thickness in a central region of the SCC structure, and a conductive medium being a vertical sidewall of the SCC structure and surrounding the insulating medium throughout the SCC thickness, the insulating medium comprises an insulating oxide or nitride material and has a higher resistance-area product than the tunnel barrier layer, the conductive medium comprises a metal or metal alloy or conductive metal nitride material and forms an electrically conductive path between the magnetic recording layer and the protective cap layer. Further, the magnetic recording layer has a sufficiently small sheet resistance so that an electric current crowding occurs in said magnetic recording layer and a spin-polarization degree can be achieved while a spin-polarized current flows nearly uniformly across the tunnel barrier layer.

A method of manufacturing such a perpendicular magnetoresistive element comprising: providing a bottom electrode; forming an MTJ stack over the bottom electrode wherein the MTJ stack comprises a magnetic reference layer, a tunnel barrier layer provided on a top surface of the magnetic reference layer and a magnetic recording layer provided on a top surface of the tunnel barrier layer; forming an insulating medium layer over the MTJ stack, forming a protective cap layer over the insulating medium layer, forming a hard mask layer over the protective cap layer and providing a method of patterning a magnetic tunnel junction which comprises: conducting a photolithographic process to form a patterned hard mask having an opening exposed area on the protective cap layer; first etching the protective cap layer and the insulating medium layer not covered by the patterned hard mask; forming a conductive encapsulation layer on the top surface of the patterned hard mask, on the top surface of the etched insulating medium layer and on vertical sidewalls of the insulating medium layer, the protective cap layer and the hard mask layer, wherein the conductive encapsulation layer comprises a metal or metal alloy or conductive metal nitride material; second etching away the conductive encapsulation layer on horizontal surfaces leaving the conductive encapsulation layer on sidewalls of the insulating medium layer, the protective cap layer and the hard mask layer, wherein vertical sidewalls of the insulating medium layer are fully covered by the conductive encapsulation layer forming a conductive medium electrically connecting the magnetic recording layer and the protective cap layer; third etching the MTJ stack to form a plurality of MTJ cells; forming a dielectric encapsulation layer on the top surface of the patterned hard mask and on sidewalls of the MTJ stack and the conductive encapsulation layer; refilling a dielectric layer; conducting a CMP process; forming a top electrode.

In a special case, the insulating medium of the SCC structure comprises a MgO layer having a thickness of at least 12 Angstroms and being made by either RF deposition of MgO or Mg deposition under 02 exposure (reactive-oxidation), and the conductive sidewall of the SCC structure comprises a Ruthenium/Tungsten (or Tungsten Nitride) bi-layer having a wall thickness of at least 15 Angstroms. Preferably, the insulating medium of the SCC structure consists of a tri-layered structure MgO(7 Angstroms)/Ru/MgO(15 Angstroms). Here, and thereafter throughout this application, each element written in the left side of “I” is stacked below (or stacked earlier than) an element written in the right side thereof.

The perpendicular magnetoresistive element further comprises a bottom electrode and a top electrode. As a write voltage is applied between the bottom electrode and the top electrode, as a result of the SCC structure, the spin-polarized current flows perpendicularly from the magnetic reference layer across the tunnel barrier layer into the magnetic recording layer, and continues to flow inside the magnetic recording layer to its edge region where the conductive sidewall of the SCC structure contacts with, and finally flows through the conductive sidewall to the protective cap layer and the hard mask layer. The spin-polarized current density is relatively uniform across the tunnel barrier layer due to the facts that both the magnetic reference layer and the magnetic recording layer have a much higher conductivity than the tunnel barrier layer, and thereafter a spin-polarized current crowding through the vertical sidewall of the SCC structure occurs and the spin-polarized current flows in the film plane of the magnetic recording layer with a much longer distance than the thickness of the magnetic recording layer, which leads to a higher spin polarization degree as well as a higher MR ratio. Both the higher spin-polarized current density and the lower PMA in edge regions of the magnetic recording layer further cause an easy and/or fast magnetic domain reversal in edge regions which further induces magnetic domain reversal in non-edge regions due to the exchange coupling and domain wall motion. Correspondingly, the reading signal is increased and the critical write current and write power are reduced with above advanced reversal modes of exchange-spring magnets of the magnetically soft-hard composite structure. The perpendicular magnetoresistive element may comprise an assisting magnetic layer between the SCC structure and the cap layer for further write power reduction.

### BRIEF DESCRIPTION OF THE DRAWINGS

FIG. 1A is a cross-sectional view showing a schematic configuration of an MTJ element 1A as a first prior art.

FIG. 1B is a cross-sectional view showing a schematic configuration of an MTJ element 1B as a second prior art.

FIG. 2A is a cross-sectional view showing a schematic configuration of an MTJ element 20 having a SCC structure, according to the first embodiment of this invention.

FIG. 2B is a schematic top view diagram of one SCC layer in an MTJ element of this invention.

FIG. 2C is a schematic cross-sectional view diagram of spin-polarized current flow across the SCC layer and the MTJ stack in an MTJ element of this invention.

FIG. 3A is a cross-sectional view showing a schematic configuration of the photolithographic process to form a patterned hard mask, according to the first embodiment.

FIG. 3B is a cross-sectional view showing a schematic configuration after etching away the protective cap layer and the insulating medium layer uncovered by the patterned hard mask and stopping at the bottom of the insulating medium layer, according to the first embodiment.

FIG. 3C is a cross-sectional view showing a schematic configuration of an MTJ element after depositing a highly conformal conductive encapsulation layer of a conductive medium by PE-CVD or atomic-layer-deposition process, according to the first embodiment.

FIG. 3D is a cross-sectional view showing a schematic configuration of an MTJ element after vertically etching away the conductive encapsulation layer on flat surfaces, according to the first embodiment.

FIG. 3E is a cross-sectional view showing a schematic configuration of an MTJ element after etching the whole MTJ stack, according to the first embodiment.

FIG. 3F is a cross-sectional view showing a schematic configuration of an MTJ array after depositing a highly conformal dielectric encapsulation layer of an insulting material by PE-CVD or atomic-layer-deposition process, according to the first embodiment.

FIG. 4 is a cross-sectional view showing a schematic configuration of an MTJ element 40 having a SCC structure, according to the second embodiment.

FIG. 5A is a cross-sectional view showing a schematic configuration of the photolithographic process to form a patterned hard mask, according to the second embodiment.

FIG. 5B is a cross-sectional view showing a schematic configuration after etching away the protective cap layer and the insulating medium layer uncovered by the patterned hard mask and stopping at the bottom of the insulating medium layer, according to the second embodiment.

FIG. 5C is a cross-sectional view showing a schematic configuration of an MTJ element after depositing a highly conformal conductive encapsulation layer of a conductive medium by PE-CVD or atomic-layer-deposition process, according to the second embodiment.

FIG. 5D is a cross-sectional view showing a schematic configuration of an MTJ element after vertically etching away the conductive encapsulation layer on flat surfaces, according to the second embodiment.

FIG. 5E is a cross-sectional view showing a schematic configuration of an MTJ element after etching the whole MTJ stack, according to the second embodiment.

FIG. 5F is a cross-sectional view showing a schematic configuration of an MTJ array after depositing a highly conformal dielectric encapsulation layer of an insulting material by PE-CVD or atomic-layer-deposition process, according to the second embodiment.

FIG. 6 is a cross-sectional view showing a schematic configuration of an MTJ element 60 having a SCC structure, according to the third embodiment.

FIG. 7 is a cross-sectional view showing a schematic configuration of an MTJ element 70 having a SCC structure, according to the fourth embodiment.

FIG. 8 is a cross-sectional view showing a schematic configuration of an MTJ element 80 having a nano-current-channel (NCC) structure, according to the fifth embodiment.

FIG. 9 is a cross-sectional view showing a schematic configuration of an MTJ element 90 having a SCC structure, according to the sixth embodiment.

### DETAILED DESCRIPTION OF THE INVENTION

In general, according to one embodiment, there is provided a magnetoresistive element comprising:

a magnetic reference layer having a perpendicular magnetic anisotropy and having an invariable magnetization direction;

a tunnel barrier layer provided on the magnetic reference layer;

a magnetic recording layer provided on the tunnel barrier layer and having a perpendicular magnetic anisotropy and a variable magnetization direction;

a sidewall-current-channel (SCC) structure provided on the magnetic recording layer;

a protective cap layer provided on the SCC structure; and

a hard mask layer provided on the protective cap layer, comprising a buffer layer and a photoresist layer for further photo-lithographic processes of a magnetoresistive element;

wherein the SCC structure comprises an insulating medium throughout the SCC thickness in a central region of the SCC structure, and a conductive medium surrounding the insulating medium and being a sidewall of the SCC structure, the insulating medium comprises an insulating oxide or nitride material and has a higher resistance-area product than the tunnel barrier layer, the conductive medium comprises a metal or metal alloy or conductive metal nitride material and forms an electrically conductive path between the magnetic recording layer and the protective cap layer.

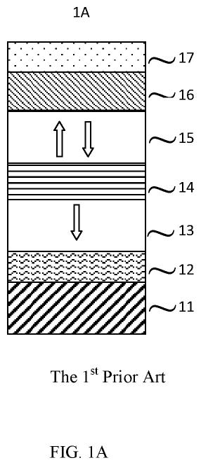

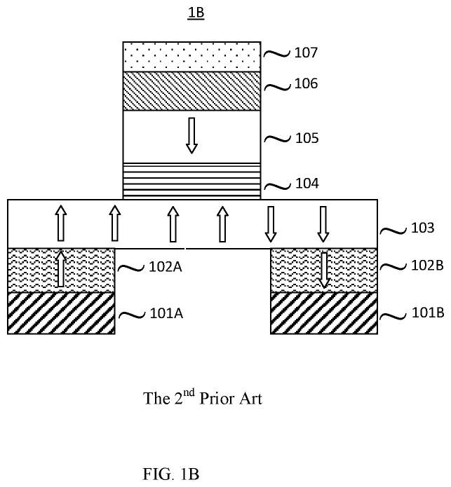

FIG. 1A is a cross-sectional view showing a configuration of an MTJ element 1A as a first prior art. As a typical perpendicular magnetic tunnel junction, the MTJ element 1A is configured by stacking a bottom electrode 11, a seed layer 12, a reference layer 13, a tunnel barrier layer 14, a recording layer 15, a cap layer 16, and a protective layer 17 in this order from the bottom.

Both the reference layer 13 and the recording layer 15 are made of ferromagnetic materials, and have uni-axial magnetic anisotropy in a direction perpendicular to a film surface. Further, both directions of easy magnetizations of the reference layer 13 and the recording layer 15 are also perpendicular to the film surfaces. A direction of easy magnetization is a direction in which the internal magnetic energy is at its minimum where no external magnetic field exists. Meanwhile, a direction of hard magnetization is a direction which the internal energy is at its maximum where no external magnetic field exists. The tunnel barrier layer 14 is made of a non-magnetic insulating metal oxide. The recording layer 15 has a variable (reversible) magnetization direction, while the reference layer 13 has an invariable (fixing) magnetization direction. The reference layer 13 is made of a ferromagnetic material having a perpendicular magnetic anisotropic energy which is sufficiently greater than the recording layer 15. This strong perpendicular magnetic anisotropy can be achieved by selecting a material, configuration and a film thickness. In this manner, a spin polarized current may only reverse the magnetization direction of the recording layer 15 while the magnetization direction of the reference layer 13 remains unchanged.

The cap layer 16 is a metal oxide layer having at least a thickness of 7 angstroms, which serves to introduce or improve perpendicular magnetic anisotropy of the recording layer 15. As an amorphous ferromagnetic material, like CoFeB, in the recording layer is thermally annealed, a crystallization process occurs to form bcc CoFe grains having epitaxial growth with (100) plane parallel to surface of the tunnel barrier layer and a perpendicular anisotropy is induced in the recording layer, as Boron elements migrate away the cap layer. Typically, the recording layer contains a metal insertion layer in the middle, which serves as a good absorber for the Boron elements in the recording layer to achieve better epitaxial CoFe crystal grains, and consequentially the recoding layer has a lower damping constant than the original CoFeB recording layer.

FIG. 1B is a cross-sectional view showing a configuration of an MTJ element 1B as a second prior art. As a domain-wall-motion magnetic tunnel junction, the MTJ element 1B comprises two bottom electrodes 101(A, B), two hard magnetic structures 102(A, B), a recording layer 103, a tunnel barrier layer 104, a reference layer 105, a cap layer 106, and a protective layer 107 in this order from the bottom. The magnetization direction distribution in the recording layer is illustrated by arrows shown in FIG. 1B. In this structure, the magnetic domain wall moves or propagates in the recording layer by applying a spin-polarized current between the two bottom electrodes and along a specific direction in the recording layer film plane.

### First Embodiment

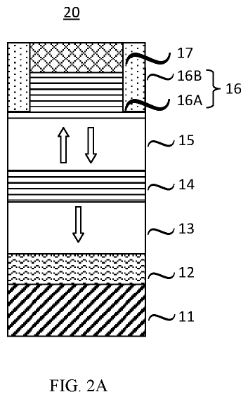

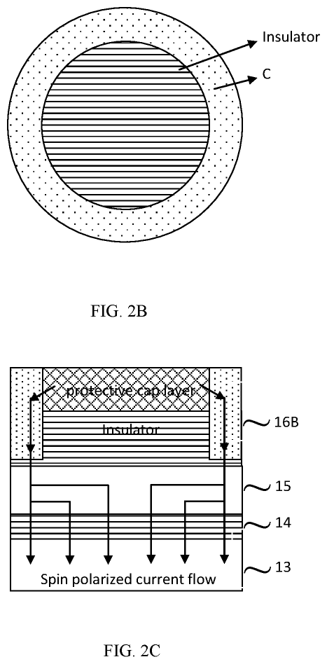

FIG. 2A is a cross-sectional view showing a schematic configuration of an MTJ element 20 having a SCC structure according to the first embodiment of this invention. The MTJ element 20 is configured by stacking a bottom electrode 11, a seed layer 12, a magnetic reference layer 13, a tunnel barrier layer 14, a magnetic recording layer 15, a sidewall-current-channel (SCC) structure 16 comprising an insulating medium 16A in a central region and a conductive medium 16B being a vertical sidewall surrounding the insulating medium 16A, and a protective cap layer 17 in this order from the bottom. FIG. 2B is a schematic top view diagram of a region of the SCC structure 16. Further, FIG. 2C is a schematic cross-sectional view diagram of spin-polarized current flow across the SCC layer and the MTJ stack in the first embodiment of this invention.

Being similar to the first prior art, the magnetic reference layer 13 and the magnetic recording layer 15 are made of ferromagnetic materials, and have uni-axial magnetic anisotropy in a direction perpendicular to a film surface. Directions of easy magnetizations of the magnetic reference layer 13 and the magnetic recording layer 15 are also perpendicular to the film surfaces. In another word, the MTJ element 20 is a perpendicular MTJ element in which magnetization directions of the magnetic reference layer 13 and the magnetic recording layer 15 face in directions perpendicular to the film surfaces. Also the tunnel barrier layer 14 is made of a non-magnetic insulating metal oxide.

The magnetic recording layer 15 has a variable (reversible) magnetization direction, while the magnetic reference layer 13 has an invariable (fixing) magnetization direction. The magnetic reference layer 13 is made of a ferromagnetic material having a perpendicular magnetic anisotropic energy which is sufficiently greater than the magnetic recording layer 15. This strong perpendicular magnetic anisotropy can be achieved by selecting a material, configuration and a film thickness. In this manner, a spin polarized current may only reverse the magnetization direction of the magnetic recording layer 15 while the magnetization direction of the reference layer 13 remains unchanged.

The SCC structure 16 comprises an insulating medium 16A of cylindrical or oval prism or other prism shapes throughout the SCC structure thickness and surrounded by a conductive medium 16B (as shown by dotted patterns of the SCC structure 16 in FIG. 2A, FIG. 2B and FIG. 2C) of sidewalls throughout the SCC structure thickness. The conductive medium 16B may directly contact with the magnetic recording layer 15, or may be separated from the magnetic recording layer 15 by a very thin insulating medium layer which has a much lower resistance-area product than the tunnel barrier layer 14 and the insulating medium 16A in the central region of the SCC structure. The magnetic recording layer 15 has two types of regions: a direct channeled region which is perpendicularly aligned with the conductive medium (i.e., the sidewall conducting channels of the SCC structure), and an indirect channeled region which is perpendicularly aligned with the insulating medium in the central region of the SCC structure. In another word, the direct channeled region of the magnetic recording layer directly contacts a bottom surface of the conductive medium of the SCC structure, while the indirect channeled region directly contacts a bottom surface of the insulating medium. Because the magnetic recording layer has a much higher conductivity than the tunnel barrier layer, when a negative voltage is applied between the top electrode and the bottom electrode of the MTJ element, a current of electrons first passes through the sidewall conducting channel of the SCC structure into the direct channeled region of the magnetic recording layer and becomes spin polarized in a direction parallel to the magnetization of the magnetic recording layer, and then a large portion of the current of spin-polarized electrons flows from the direct channeled region of the magnetic recording layer to the in-direct channeled region of the magnetic recording layer, which is normally called current crowding effect. And finally the current of spin-polarized electrons approximately uniformly flows across the tunnel barrier layer when the characteristic length of the current crowding, which is defined as square-root of the ratio between the area-resistance product of the MTJ and the sheet resistance of the magnetic recording layer, is much larger than the radius (or half diameter) of the MTJ. When a positive voltage is applied between the top electrode and the bottom electrode, the path which a current of electrons takes is simply reversed. Since the sheet resistance of the magnetic recording layer is the ratio between its resistivity (˜300 micro-ohm.cm) and its thickness (˜1.5 nm), it is estimated to be 2000 ohms. If the area-resistance product of the MTJ is about 8 ohms-micron², the characteristic length of current crowding is more than 60 nm. For an advanced technology, the radius of the MTJ radius is getting smaller than 20 nm, so that the series resistance generated from the current crowding effect becomes negligible. As an applied current flows perpendicularly across nanometer-thick ferromagnetic films in an MTJ device, i.e., in a typical Current-Perpendicular-to-Plane (CPP) mode, the spin-polarization degree decreases very faster as the film thickness decreases, consequently the MR ratio decreases very faster as the film thickness decreases. For example, in an in-plane MTJ device, the magnetic recording layer needs to be ˜3 nm thick or more in order to achieve a high MR ratio of 400% or more. However, in a perpendicular MTJ device, the magnetic recording layer has an upper limit of thickness (normally less than 2 nm) for a sufficient perpendicular anisotropy to meet its thermal stability requirement. In this invention, due to the current crowding effect, a majority of electric current is forced to flow along the film plane of the magnetic recording layer before it passes across the tunnel barrier layer, and an enhanced spin-polarization degree, as well as a higher MR ratio, can be achieved.

In the SCC structure 16, as shown in FIGS. 2A and 2B, “C” represents sidewall conducting channel (dotted pattern at periphery) which is highly conductive, while “Insulator” represents insulating medium (striped pattern in center) which is non-conductive or very poorly conductive. The sidewall conducting channel comprises a nonmagnetic metal material or metal alloy material or conductive metal nitride material, which may have a high conductivity similar to the magnetic recording layer material or the protective cap layer material. The choice of the sidewall conducting channel material includes W, WN, Ru, Ta, TaN, Mo, MoN, TiN, etc. The sidewall conducting channel can be either a single layer or multilayer. The wall thickness of the sidewall conducting channel is preferred to be between 2 nm and 5 nm. The insulating medium consists of an oxide or a nitride, such as MgO, Al₂O₃, SiO₂, SiNₓ, etc., having a larger thickness than the tunnel barrier layer 14, such that it has a much higher resistance-area product (RA) than the tunnel barrier layer 14. Note that the resistance of a metal oxide, such as MgO, Al₂O₃ etc., is typically an exponential function of its thickness, i.e., the resistance increases extremely fast with its thickness. In a ferromagnetic material, an internal magnetic field can generate a spin-polarized current because majority and minority carriers have different conductivities. Spin currents generated within ferromagnetic materials have spin directions that are aligned with the magnetization. An electric current obtains a spin polarization degree depending on the path length which free electrons are traveling inside a ferromagnetic material. The spin polarized current generated by a ferromagnetic layer can further transfer its spin angular momentum to another ferromagnetic layer within the same hetero-structure. FIG. 2C is a schematic cross-sectional view diagram of spin-polarized current flow across the SCC layer and the MTJ stack in an MTJ element of this invention. As the characteristic length of current crowding is much larger than the radius of the MTJ, the electric current flows along the film plane of the magnetic recording layer between the sidewall conducting channel and the tunnel barrier layer, in which electrons travel much longer paths inside the magnetic recording layer than the film thickness of the magnetic recording layer, and obtains a higher spin-polarization degree than a simple CPP mode in which a current of electrons passes only perpendicularly through the thickness of the magnetic recording layer. For an MgO MTJ, a moderate increase in the spin-polarization degree would lead to a greatly increased MR ratio. So, this invention provides a route of engineering spin-polarized electron flow and transfer through a magnetoresistive device.

The perpendicular magnetoresistive element 20 further comprises a bottom electrode and a top electrode (not shown here). As a write voltage is applied between the bottom electrode and the top electrode, as a result of above SCC structure, an inhomogeneous current distribution across the magnetic recording layer between the tunnel barrier layer and the SCC structure exists, and parts of the spin-polarized current travel longer paths inside the magnetic recording layer than others, which would cause a higher spin-transfer-torque efficiency. Since the magnetic recording layer has a similar magnetic moment and perpendicular magnetic anisotropies (PMAs) as a conventional pSTT-MRAM element which doesn't have the SCC structure, i.e., the energy barrier is similar, the critical switching current is expected to be smaller due to the higher spin-transfer-torque efficiency in present invention. And more, since indirect channeled regions of the magnetic recording layer may have different interfacial perpendicular magnetic anisotropies (PMAs) than direct channeled regions of the magnetic recording layer, the magnetic recording layer is equivalently a composite magnetic layer comprising soft magnets and hard magnets which are coupled together through ferromagnetic exchange coupling. In another word, it is a magnetically soft-hard composite structure, or a single-layered exchange-spring structure, in which each soft magnet is ferromagnetically exchange coupled to its adjacent hard magnets, and vice versa. In a typical MRAM device, the thermal stability requirement is E_{b}>60 k_{B}T. Here, E_{b} is the energy barrier for magnetization reversal of the magnetic recording layer, k_{B} is the Boltzmann constant and T is the absolute temperature of the device. With a proper exchange coupling, E_{b} of a composite magnetic layer comprising soft magnets and hard magnets is expected to be similar to that of a magnetic layer consisting of all hard magnets. For pSTT-current driven switch, it is expected to have smaller write current amplitudes and shorter pulse durations required to reverse the magnetization compared to a homogeneous magnetic recording layer of comparable thermal stability. Both the higher spin-polarization degree and lower PMA regions cause fast magnetic domain reversals and propagates to higher PMA regions through domain wall motions due to the spin-transfer-torque effect and the exchange coupling between lower PMA regions and higher PMA regions, and correspondingly the critical write current and write power are reduced.

An example configuration of the MTJ element 20 will be described below. The magnetic reference layer 13 is made of Pt(around 5 nm)/[Co/Pt]₃/Co(around 0.5 nm)/Ru(around 0.5 nm)/Co(around 0.5 nm)/W(around 0.2 nm)/CoFeB(around 1 nm). The tunnel barrier layer 14 is made of MgO(around 1 nm). The magnetic recording layer 15 is made of CoFeB(around 1.5 nm)/Mo(0.2 nm)/CoFeB(around 0.6 nm). The insulating medium 16A of the SCC structure is made of MgO(around 1.5 nm), and the sidewall conductive medium 16B of the SCC structure is made of Ru/WN. The protective cap layer 17 is made of Ru/Ta(around 10 nm). The seed layer 12 is made of Ta(around 20 nm)/Ru(around 20 nm)/Ta(around 20 nm). Here, and thereafter throughout this application, each element written in the left side of “I” is stacked below (or stacked earlier than) an element written in the right side thereof.

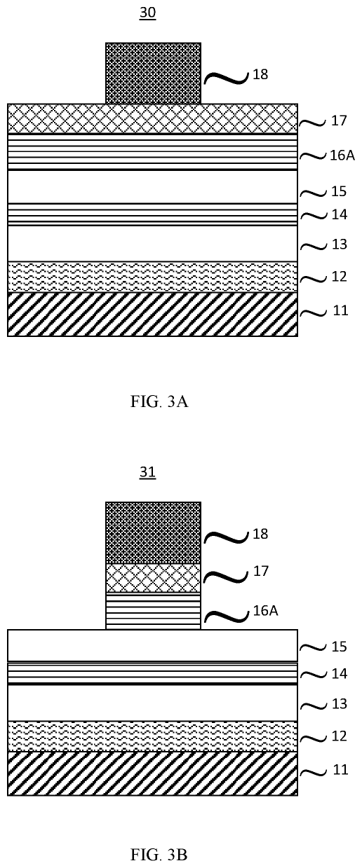

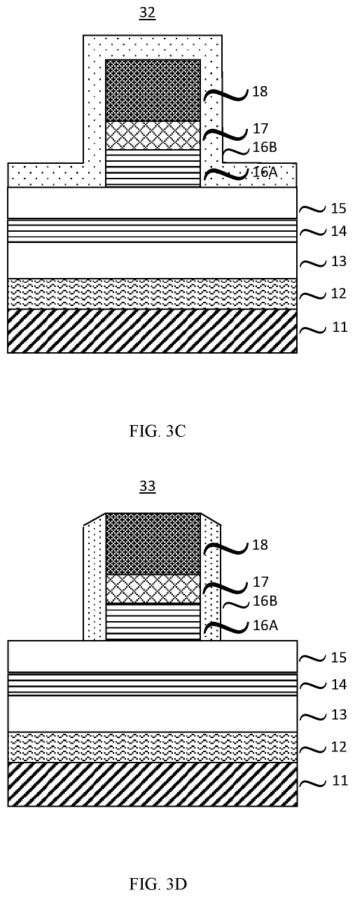

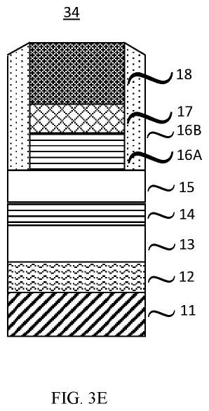

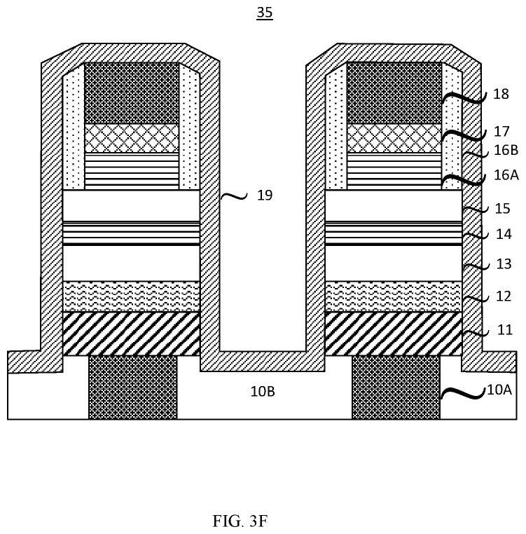

Through schematic configurations after major fabrication steps in sequence, a detailed fabrication method of MTJ elements having a SCC structure in the first embodiment is illustrated in FIGS. 3(A, B, C, D, E, F) as follows. In general, a SCC structure can be formed by sequential steps comprising of: forming of the insulating medium 16A on top surface of the recording layer 15, forming of protective cap layer 17 on the insulating medium 16A, forming of the hard mask layer on the protective cap layer 17, performing a photolithographic process to form a patterned hard mask 18, etching away the protective cap layer and the insulating medium layer uncovered by the patterned hard mask 18, forming a highly conformal conductive encapsulation layer of a conductive medium, performing a vertically etching process to remove the conductive encapsulation layer on flat surfaces and leaving the conductive encapsulation layer 16B on sidewalls of the insulating medium layer 16A, the protective cap layer 17 and the hard mask 18, further etching the whole MTJ stack and forming a highly conformal dielectric encapsulation layer 19 of a dielectric material (i.e., an insulting material), as shown by schematic diagrams in FIGS. 3(A-F). FIG. 3A is a cross-sectional view showing a schematic configuration of an MTJ element 30 after using photolithographic process to form a patterned hard mask, according to the first embodiment. The MTJ element 30 is configured by stacking a bottom electrode 11, a seed layer 12, a magnetic reference layer 13, a tunnel barrier layer 14, a magnetic recording layer 15, an insulating medium 16A, a protective cap layer 17 and a patterned hard mask 18 in this order from the bottom. The insulating medium 16A is preferred to be MgO or other stable metal oxide having a thickness of at least 12 Angstroms and a resistance-area product of at least 50 ohms-micron². The formation of MgO comprises either RF deposition of MgO or Mg deposition under O₂ exposure (reactive-oxidation) and optionally post-annealed.

FIG. 3B is a cross-sectional view showing a schematic configuration after etching away the protective cap layer and the insulating medium layer uncovered by the patterned hard mask and stopping near the bottom surface of the insulating medium layer. Since the most part of the insulating medium uncovered by the patterned hard mask is etched away, remaining insulating medium is very thin (not shown here) and its resistance-area product is very small so that it becomes very conductive, while the insulating medium layer 16A covered by the patterned hard mask is untouched and has a very high resistance-area product. FIG. 3C is a cross-sectional view showing a schematic configuration of an MTJ element after depositing a highly conformal conductive encapsulation layer of a conductive medium by PE-CVD or atomic-layer-deposition process. Such a highly conformal conductive encapsulation layer 16B has about the same thickness on the wall and on the flat surface. The conductive encapsulation layer comprises at least one selected from the group consisting of a Ru layer, a W layer, a Ta layer, a Mo layer, a Hf layer, a WN layer, a TaN layer, a HfN layer, a TiN layer, a Fe layer, a CoFe layer, a CoFeB layer, etc. FIG. 3D is a cross-sectional view showing a schematic configuration of an MTJ element after vertically etching away the conductive encapsulation layer on flat surfaces and leaving the conductive encapsulation layer as the sidewall conductive channel 16B on sidewalls of the insulating medium layer 16A, the protective cap layer 17 and the hard mask 18.

FIG. 3E is a cross-sectional view showing a schematic configuration of an MTJ element 34 after etching the whole MTJ stack, including the bottom electrode. The MTJ element 34 is configured by stacking a bottom electrode 11, a seed layer 12, a magnetic reference layer 13, a tunnel barrier layer 14, a magnetic recording layer 15, an insulating medium 16A, a sidewall conductive channel 16B, a protective cap layer 17 and a patterned hard mask 18 in this order from the bottom. And FIG. 3F is a cross-sectional view showing a schematic configuration of an MTJ array after depositing a highly conformal dielectric encapsulation layer 19 of a dielectric material by PE-CVD or atomic-layer-deposition process. A typical dielectric material is SiNₓ which would prevent oxidization of the MTJ from a dielectric oxide refilled in a MTJ pillar array in a later process. In FIG. 3F, 10A represents a bottom via, which connects the MTJ element to an underneath select transistor (not shown here), and 10B represents a dielectric material. The step of forming the conductive encapsulation layer is in-situ performed with the step of etching the insulating medium layer uncovered by the hard mask and the step of etching the conductive encapsulation layer on flat surfaces in a production tool having a vacuum environment, and wherein no vacuum-break occurs to the vacuum environment from a time the step of etching the insulating medium layer is started to a time the step of forming the dielectric encapsulation layer is ended. After the dielectric encapsulation process, a dielectric SiO₂ is refilled to cover the MTJ pillar array, followed by a CMP process, a top electrode connection process and a bit-line process, which are not shown here.

### Second Embodiment

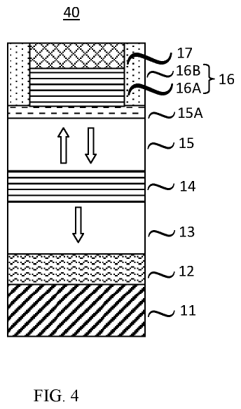

FIG. 4 is a cross-sectional view showing a schematic configuration of an MTJ element 40 having a SCC structure according to the second embodiment of this invention. The MTJ element 40 is configured by stacking a bottom electrode 11, a seed layer 12, a magnetic reference layer 13, a tunnel barrier layer 14, a magnetic recording layer 15, a perpendicular anisotropy enhancement layer 15A, a nonmagnetic sidewall-current-channel (SCC) structure 16 comprising an insulating medium 16A and a conductive medium 16B being a sidewall surrounding the insulating medium 16A, and a protective cap layer 17 in this order from the bottom.

Being similar to the first prior art, the magnetic reference layer 13 and the magnetic recording layer 15 are made of ferromagnetic materials, and have uni-axial magnetic anisotropy in a direction perpendicular to a film surface. Directions of easy magnetizations of the magnetic reference layer 13 and the magnetic recording layer 15 are also perpendicular to the film surfaces. In another word, the MTJ element 40 is a perpendicular MTJ element in which magnetization directions of the magnetic reference layer 13 and the magnetic recording layer 15 face in directions perpendicular to the film surfaces. Also the tunnel barrier layer 14 is made of a non-magnetic insulating metal oxide. The magnetic recording layer 15 has a variable (reversible) magnetization direction, while the magnetic reference layer 13 has an invariable (fixing) magnetization direction. The magnetic reference layer 13 is made of a ferromagnetic material having a perpendicular magnetic anisotropic energy which is sufficiently greater than the magnetic recording layer 15. This strong perpendicular magnetic anisotropy can be achieved by selecting a material, configuration and a film thickness. In this manner, a spin polarized current may only reverse the magnetization direction of the magnetic recording layer 15 while the magnetization direction of the reference layer 13 remains unchanged.

The SCC structure 16 comprises an insulating medium 16A of cylindrical or oval prism or other prism shapes throughout the SCC structure thickness and surrounded by a conductive medium or sidewall 16B throughout the SCC structure thickness. The conductive sidewall 16B directly contacts with the perpendicular anisotropy enhancement layer 15A which is conductive. The magnetic recording layer 15 has two types of regions: a direct channeled region which is perpendicularly aligned with the sidewall conducting channel of the SCC structure, and an indirect channeled region which is perpendicularly aligned with the insulating medium of the SCC structure. Because the magnetic recording layer has a much higher conductivity than the tunnel barrier layer, a spin-polarized current flows first through the sidewall conducting channels of the SCC structure and the perpendicular anisotropy enhancement layer into the magnetic recording layer. And after a part of the spin-polarized current flows from the direct channeled region of the magnetic recording layer to the in-direct channeled region of the magnetic recording layer, which is normally called current crowding effect, the spin-polarized current approximately flows across the tunnel barrier layer when the characteristic length of the current crowding in the magnetic recording layer is much larger than the radius (or half diameter) of the MTJ. As an applied current flows perpendicularly across nano-meter thick ferromagnetic films in an MTJ device, the spin-polarization degree decreases very faster as the film thickness decreases, consequently the MR ratio decreases very faster as the film thickness decreases. Due to the current crowding effect, a large portion of electric current is forced to flow along the film plane of the magnetic recording layer before it passes across the tunnel barrier layer, and obtains an enhanced spin-polarization degree as well as a higher MR ratio.

Being similar to the first embodiment, the sidewall conducting channel which is highly conductive, while the insulating medium is non-conductive or very poorly conductive. The sidewall conducting channel comprises a nonmagnetic metal material or metal alloy material or metal nitride material, which may have a high conductivity similar to the magnetic recording layer material or the protective cap layer material. The perpendicular anisotropy enhancement layer 15A comprises at least one layer of Ru, Mg, Mo, W, Ta, Ti, Cr, V, Hf, Nb, Zr, Fe, Co, Ni, Al, Cu, Pt, Au, Ag, Rh, Ir, Os, Re, or alloy thereof, or oxide thereof. The choice of the sidewall conducting channel material includes W, WN, Ru, Ta, TaN, Mo, MoN, TiN, etc. The sidewall conducting channel 16B can be either a single layer or multilayer. The width of the sidewall conducting channel is preferred to be between 2 nm and 5 nm. The insulating medium 16A consists of an oxide or a nitride, such as MgO, Al₂O₃, SiO₂, SiNₓ, etc., having a larger thickness than the tunnel barrier layer 14, such that it has a much higher resistance-area product (RA) than the tunnel barrier layer 14. Note that the resistance of a metal oxide, such as MgO, Al₂O₃ etc., is typically an exponential function of its thickness, i.e., the resistance increases extremely fast with its thickness.

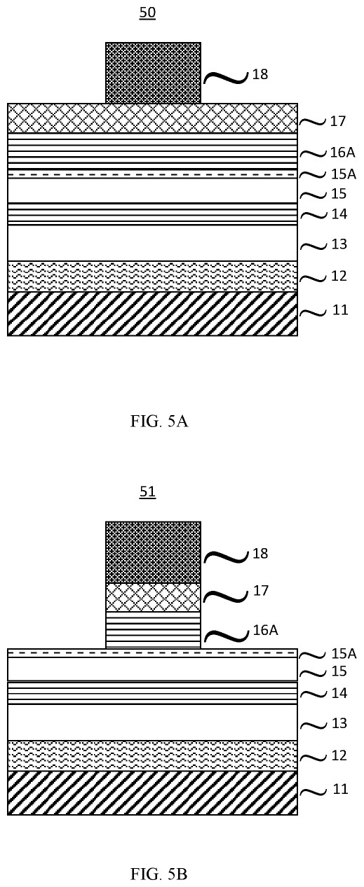

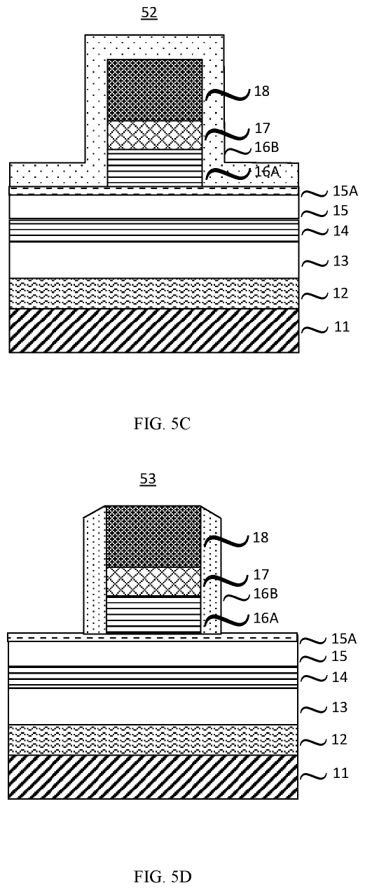

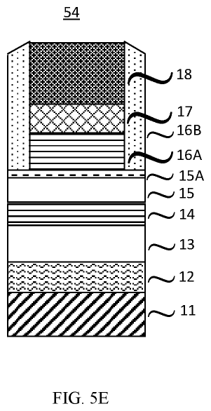

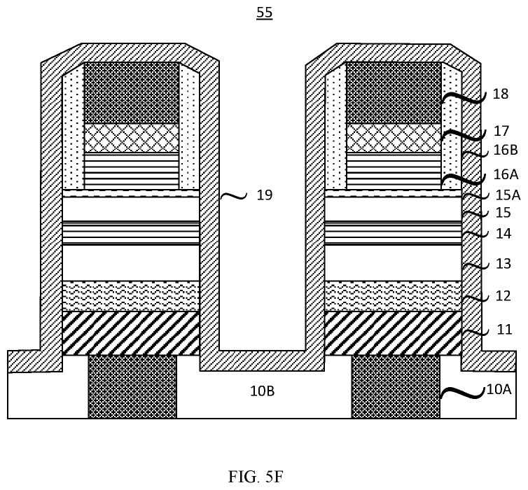

An example configuration of the MTJ element 40 will be described below. The magnetic reference layer 13 is made of MgO/FeO/[Fe/Pt]₅/Fe/Cr/Fe/CoFe(around 1 nm). The tunnel barrier layer 14 is made of MgO(around 1 nm). The magnetic recording layer 15 is made of Fe/CoFeB(around 1.4 nm). The perpendicular anisotropy enhancement layer 15A is made of Mo(0.2 nm)/MgO(0.7 nm)/Ru(0.5 nm). The insulating medium of the SCC structure 16 is made of MgO(around 2 nm), and the sidewall conductive medium of the SCC structure 16 is made of Mo/Ru/WN. The protective cap layer 17 is made of Ru/Ta(around 10 nm). The seed layer 12 is made of Ta(around 20 nm)/Ru(around 20 nm)/Ta(around 20 nm). Detailed schematic configurations of MTJ elements having a SCC structure after each major fabrication step in sequence and their forming methods are illustrated in FIGS. 5(A, B, C, D, E, F) as follows.

FIG. 5A is a cross-sectional view showing a schematic configuration of an MTJ element 50 after using photolithographic process to form a patterned hard mask, according to the first embodiment. The MTJ element 50 is configured by stacking a bottom electrode 11, a seed layer 12, a magnetic reference layer 13, a tunnel barrier layer 14, a magnetic recording layer 15, a perpendicular anisotropy enhancement layer 15A, an insulating medium 16A, a protective cap layer 17 and a patterned hard mask 18 in this order from the bottom. The MTJ has a resistance-area product of 7 ohms-micron². The insulating medium 16A is preferred to be MgO or other stable metal oxide having a thickness of at least 12 Angstroms and a resistance-area product of at least 100 ohms-micron².

FIG. 5B is a cross-sectional view showing a schematic configuration after etching away the protective cap layer and the insulating medium layer uncovered by the patterned hard mask and stopping at the bottom of the insulating medium layer. Since the most part of the insulating medium uncovered by the patterned hard mask is etched away, remaining insulating medium is very thin (not shown here) and its resistance-area product is very small so that it becomes very conductive, while the insulating medium layer covered by the patterned hard mask is untouched and has a very high resistance-area product. FIG. 5C is a cross-sectional view showing a schematic configuration of an MTJ element after depositing a highly conformal conductive encapsulation layer of a conductive medium by PE-CVD or atomic-layer-deposition process. Such a highly conformal conductive encapsulation layer has about the same thickness on the wall and on the flat surface. The conductive encapsulation layer comprises at least one selected from the group consisting of a Ru layer, a W layer, a Ta layer, a Mo layer, a Hf layer, a WN layer, a TaN layer, a HfN layer, a TiN layer, a Fe layer, a CoFe layer, a CoFeB layer, etc. After forming the conductive encapsulation layer, a sacrificial encapsulation layer of a dielectric material, such as SiNₓ, is deposited. Here, the sacrificial encapsulation layer would serve to better control the final wall thickness of the conductive encapsulation layer on walls of the insulating layer, the protective layer and the hard mask layer without significant etching from future etching processes which may only etch away the sacrificial encapsulation layer. FIG. 5D is a cross-sectional view showing a schematic configuration of an MTJ element after vertically etching away the conductive encapsulation layer on flat surfaces and leaving the conductive encapsulation layer 16B on sidewalls of the insulating medium layer 16A, the protective cap layer 17 and the hard mask 18.

FIG. 5E is a cross-sectional view showing a schematic configuration of an MTJ element after etching the whole MTJ stack, including the bottom electrode. And FIG. 5F is a cross-sectional view showing a schematic configuration of an MTJ array after depositing a highly conformal dielectric encapsulation layer 19 of a dielectric material (i.e., an insulting material) by PE-CVD or atomic-layer-deposition process. A typical dielectric material is SiNₓ which would prevent oxidization of the MTJ from a dielectric oxide refilled in a MTJ pillar array. In FIG. 5F, 10A represents a bottom via, which connects the MTJ element to an underneath select transistor, and 10B represents a dielectric material. After the dielectric encapsulation process, a dielectric SiO₂ is refilled to cover the MTJ pillar array, followed by a CMP process, a top electrode connection process and a bit-line process, which are not shown here.

### Third Embodiment

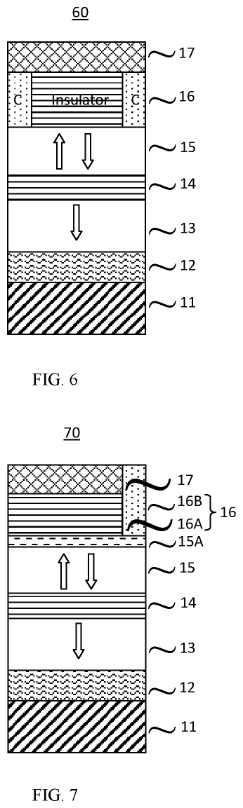

FIG. 6 is a cross-sectional view showing a deposition processing of an alternative SCC structure, according to the third embodiment of this invention. The MTJ element 60 is configured by stacking a bottom electrode 11, a seed layer 12, a magnetic reference layer 13, a tunnel barrier layer 14, a magnetic recording layer 15, a nonmagnetic sidewall-current-channel (SCC) structure 16 comprising an insulating medium 16A and a conductive medium 16B being a sidewall surrounding the insulating medium 16A, and a protective cap layer 17 in this order from the bottom. Unlike the first and second embodiments, this alternative SCC structure has a side conductive wall only surrounding the insulating medium, instead of extending all the way to surround the hard mask. And more, the SCC structure of this embodiment is formed by patterning the insulating medium immediately after its deposition.

### Fourth Embodiment

As the fourth embodiment shown in FIG. 7, the MTJ element 70 is configured by stacking a bottom electrode 11, a seed layer 12, a magnetic reference layer 13, a tunnel barrier layer 14, a magnetic recording layer 15, a perpendicular anisotropy enhancement layer 15A, a nonmagnetic sidewall-current-channel (SCC) structure 16 comprising an insulating medium 16A and a conductive medium 16B being a sidewall, and a protective cap layer 17 in this order from the bottom. Different from previous embodiments, the conductive sidewall 16B is only on one side of the element, which can be fabricated by either asymmetrically depositing the conductive medium or an additional canted etching of the conductive medium. In this structure, an electric current passes through the one-sided sidewall and also flows in-plane along the magnetic recording layer before nearly uniformly passing through the tunnel barrier layer to the magnetic reference layer.

All of above embodiments may further comprise an assisting magnetic layer provided in proximity of the magnetic recording layer, especially between the SCC structure and the cap layer. The assisting magnetic layer has a magnetization direction either in the film plane or perpendicular to the film surface, and may provide an additional spin-transfer-torque on the magnetic recording layer, or may provide a shielding effect to reduce stray demag field from the magnetic recording layer during the switching process. The assisting magnetic layer may comprise at least one of an iron (Fe) layer, a cobalt (Co) layer, an alloy layer of cobalt iron (CoFe), an alloy layer of iron boron (FeB), an alloy layer of cobalt boron (CoB), an alloy layer of cobalt iron boron (CoFeB), an alloy layer of cobalt nickel iron (CoNiFe), an alloy layer of cobalt nickel (CoNi), an alloy layer of iron platinum (FePt), an alloy layer of iron palladium (FePd), an alloy layer of iron nickel (FeNi), a laminated layer of (Fe/Co)ₙ, a laminated layer of (Fe/CoFe)ₙ, a laminated layer of (Fe/Pt)ₙ, a laminated layer of (Fe/Pd)ₙ and a laminated layer of (Fe/Ni)ₙ, where n is a lamination number being at least 3, and the B composition percentage is no more than 35%. The assisting magnetic layer may be a multilayer of ferromagnetic materials.

### Fifth Embodiment

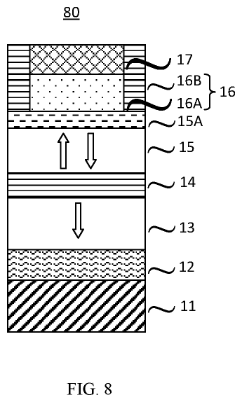

As the fifth embodiment shown in FIG. 8, the MTJ element 80 is configured by stacking a bottom electrode 11, a seed layer 12, a magnetic reference layer 13, a tunnel barrier layer 14, a magnetic recording layer 15, a perpendicular anisotropy enhancement layer 15A, a nonmagnetic nano-current-channel (NCC) structure 16 comprising a conductive medium 16A and an insulating medium 16B being a sidewall, and a protective cap layer 17 in this order from the bottom. The magnetic recording layer has a sufficiently small sheet resistance so that an electric current crowding occurs in the magnetic recording layer due to the NCC structure while the current density across the tunnel barrier layer is substantially uniform when a voltage is applied to the MTJ element. The NCC structure 16 can be formed by sequential steps comprising of: forming of the conductive medium 16A on top surface of the perpendicular anisotropy enhancement layer 15A, forming of protective cap layer 17 on the conductive medium 16A, forming of the hard mask layer on the protective cap layer 17, performing a photolithographic process to form a patterned hard mask 18, etching away the protective cap layer and the conductive medium layer uncovered by the patterned hard mask 18, forming a highly conformal insulating encapsulation layer of an insulating medium, performing a vertically etching process to remove the insulating encapsulation layer on flat surfaces and leaving the insulating encapsulation layer 16B on sidewalls of the conductive medium layer 16A, the protective cap layer 17 and the hard mask 18, further etching the whole MTJ stack and forming a highly conformal dielectric encapsulation layer 19 of a dielectric material.

### Sixth Embodiment

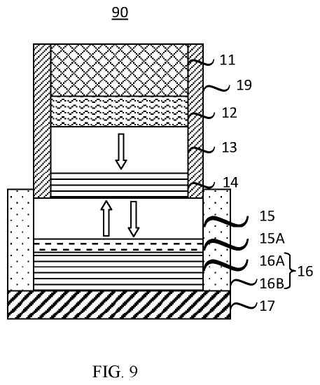

A SCC structure can be also applied to a top-pinned MTJ element as well as a spin-orbit torque magnetic random access memory (SOT-MRAM) element. As the sixth embodiment shown in FIG. 9, the MTJ element 90 is configured by stacking a hard mask layer 11, a protective cap layer 12, a magnetic reference layer 13, a tunnel barrier layer 14, a magnetic recording layer 15, a perpendicular anisotropy enhancement layer 15A, a SCC structure 16 comprising an insulating medium 16A and a conductive medium 16B being a sidewall, and a bottom layer 17 in this order from the top. The magnetic recording layer has a sufficiently small sheet resistance so that an electric current crowding occurs in the magnetic recording layer due to the SCC structure while the current density across the tunnel barrier layer is substantially uniform when a voltage is applied to the MTJ element.

The SCC structure 16 of the sixth embodiment in this invention can be formed by sequential steps comprising of: performing a first photolithographic process to form a patterned hard mask 11, etching away the protective cap layer 12 and the magnetic reference layer 13 uncovered by the patterned hard mask 11, forming a highly conformal insulating encapsulation layer of an insulating material, performing a vertically etching process to remove the insulating encapsulation layer on flat surfaces and leaving the insulating encapsulation layer 19 on sidewalls of the magnetic reference layer 13, the protective cap layer 12 and the patterned hard mask 11, further etching away the tunnel barrier layer 14, the magnetic recording layer 15, the perpendicular anisotropy enhancement layer 15A and the insulating medium 16A uncovered by the patterned hard mask 11 and the insulating encapsulation layer 19, forming of the conductive medium by collimated deposition and etching away the conductive medium on the vertical wall of the MTJ and leaving the conductive medium 16B on flat surface, the conductive medium 16B electrically connects the bottom electrode 17 to the magnetic recording layer 15 and the perpendicular anisotropy enhancement layer 16, further performing a second photolithographic process to pattern the conductive medium 16B and the bottom electrode 17 to make a MTJ pillar array. After the second photolithographic process, a dielectric SiO₂ is refilled to cover the MTJ pillar array, followed by a CMP process, a top electrode connection process and a bit-line process, which are not shown here.

While certain embodiments have been described above, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A magnetoresistive element comprising:
a magnetic reference layer having a perpendicular magnetic anisotropy and having an invariable magnetization direction;
a tunnel barrier layer provided on the magnetic reference layer;
a magnetic recording layer provided on the tunnel barrier layer and having a perpendicular magnetic anisotropy and a variable magnetization direction;
a sidewall-current-channel (SCC) structure provided on the magnetic recording layer, wherein the SCC structure comprises an insulating medium in a central region of the SCC structure, and a conductive medium being a vertical sidewall of the SCC structure and surrounding the insulating medium;
a protective cap layer provided on the insulating medium; and
a hard mask layer provided on the protective cap layer;
wherein the tunnel barrier layer has a first resistance-area product (RA₁), the insulating medium comprises an insulating oxide or nitride material and has a second resistance-area product (RA₂), the second resistance-area product (RA₂) is higher than the first resistance-area product (RA₁), the conductive medium comprises a conductive material making electrical connection between the magnetic recording layer and the protective cap layer.

2. The element of claim 1, wherein said conductive medium further extends along a vertical direction to be vertical sidewalls of said protective cap layer and said hard mask layer, and surrounds said protective cap layer and said hard mask layer.

3. The element of claim 1, wherein said conductive medium comprises at least one layer of metal or metal alloy or conductive metal nitride material, preferred to be Ru, Mo, W, Ta, Ti, Cr, V, Hf, Nb, Zr, Fe, Co, Ni, Cu, Pt, Au, Ag, Rh, Ir, Os, Re, or alloy thereof, or nitride thereof.

4. The element of claim 1, wherein said conductive medium has a wall thickness between 1.5 nm and 5.0 nm, and has substantially the same outer diameter as said magnetic recording layer.

5. The element of claim 1, wherein said insulating medium comprises at least one layer of oxide or nitride, preferred to be selected from the group consisting of MgO, MgAl₂O₄, Al₂O₃, HfO₂, ZrO₂, TiO₂, SiO₂, Y₂O₃, RuO, OsO, TcO, ReO, BeO, SiN, RuN, OsN, TcN, ReN, NiO, CoO, FeO, FeCoO₂, NiFeO₂, CoNiO₂, MnO, CrO, VO, TiO, ZnO and CdO.

6. The element of claim 1, wherein said second resistance-area product (RA₂) is at least 5 times said first resistance-area product (RA₁).

7. The element of claim 1, wherein said insulating medium has a thickness of at least 12 angstroms.

8. The element of claim 1, wherein said magnetic recording layer has an in-plane sheet resistance Rs, and a current-crowding characteristic length being the square-root of the ratio between said first resistance-area product (RA₁) and said in-plane sheet resistance Rs, said current-crowding characteristic length being larger than the outer diameter of said insulating medium.

9. The element of claim 1, further comprising a perpendicular anisotropy enhancement layer between said magnetic recording layer and said SCC structure, wherein said perpendicular anisotropy enhancement layer comprises at least one layer of Ru, Mg, Mo, W, Ta, Ti, Cr, V, Hf, Nb, Zr, Fe, Co, Ni, Al, Cu, Pt, Au, Ag, Rh, Ir, Os, Re, or alloy thereof, or oxide thereof.

10. The element of claim 1, further comprising an upper electrode and a lower electrode which sandwich said magnetoresistive element, and further comprising a write circuit which bi-directionally supplies a current to said magnetoresistive element, and a select transistor electrically connected between said magnetoresistive elements and said write circuit.

11. A method of manufacturing a perpendicular magnetic tunnel junction (put) element having a sidewall-current-channel (SCC) structure for being used in a magnetic memory device, the method comprising the steps of:
providing a bottom electrode;
depositing an MTJ stack over the bottom electrode, wherein the MTJ stack comprises at least a magnetic reference layer, a tunnel barrier layer provided on a top surface of the magnetic reference layer and a magnetic recording layer provided on a top surface of the tunnel barrier layer;
depositing an insulating medium layer over the MTJ stack;
depositing a protective cap layer over the insulating medium layer;
depositing a hard mask layer over the protective cap layer;
conducting a photolithographic process to form a patterned hard mask having an opening exposed area on the protective cap layer;
first etching the protective cap layer and the insulating medium layer not covered by the patterned hard mask;
forming a conductive encapsulation layer on the top surface of the patterned hard mask, on the top surface of the etched insulating medium layer and on sidewalls of the insulating medium layer, the protective cap layer and the hard mask, wherein the conductive encapsulation layer is a conformal layer made of an electrically conductive material;
second etching away the conductive encapsulation layer on horizontal surfaces, leaving the conductive encapsulation layer on vertical sidewalls of the insulating medium layer, the protective cap layer and the hard mask, wherein sidewalls of the insulating medium layer are covered by the conductive encapsulation layer forming a conductive medium electrically connecting the magnetic recording layer and the protective cap layer;
third etching the MTJ stack to form a plurality of MTJ cells; and
forming a dielectric encapsulation layer on the top surface of the patterned hard mask and on sidewalls of the MTJ stack and the conductive encapsulation layer, wherein the dielectric encapsulation layer is made of an electrically insulating material.

12. The element of claim 11, wherein said conductive medium comprises at least one layer of metal or metal alloy or conductive metal nitride material, preferred to be Ru, Mo, W, Ta, Ti, Cr, V, Hf, Nb, Zr, Fe, Co, Ni, Cu, Pt, Au, Ag, Rh, Ir, Os, Re, or alloy thereof, or nitride thereof.

13. The element of claim 11, wherein said insulating medium layer has a thickness of at least 12 angstroms and comprises at least one layer of oxide or nitride, preferred to be selected from the group consisting of MgO, MgAl₂O₄, Al₂O₃, HfO₂, ZrO₂, TiO₂, SiO₂, Y₂O₃, RuO, OsO, TcO, ReO, BeO, SiN, RuN, OsN, TcN, ReN, NiO, CoO, FeO, FeCoO₂, NiFeO₂, CoNiO₂, MnO, CrO, VO, TiO, ZnO and CdO.

14. The element of claim 11, wherein said first etching stops within a lower-half portion of said insulating medium layer or at a bottom surface of said insulating medium layer.

15. The element of claim 11, further comprising, after forming said conductive encapsulation layer, a sacrificial encapsulation layer of a dielectric material, the dielectric material is preferred to at least one selected from the group consisting of SiNₓ, SiO₂, SiOₓN_{y}, SiC and amorphous Carbon.

16. The element of claim 11, wherein said second etching comprises a vertical etching using collimated reactive ion beam or collimated ion beam to remove said conductive encapsulation layer on horizontal surfaces.

17. The element of claim 11, further comprising, after depositing said MTJ stack, forming a perpendicular anisotropy enhancement layer, wherein said perpendicular anisotropy enhancement layer comprises at least one layer of Ru, Mg, Mo, W, Ta, Ti, Cr, V, Hf, Nb, Zr, Fe, Co, Ni, Al, Cu, Pt, Au, Ag, Rh, Ir, Os, Re, or alloy thereof, or oxide thereof.

18. The element of claim 11, further comprising, after forming said dielectric encapsulation layer, refilling a dielectric layer, conducting a CMP process and forming a top electrode.

19. A magnetoresistive element comprising:
a magnetic reference layer having a perpendicular magnetic anisotropy and having an invariable magnetization direction;
a tunnel barrier layer provided on the magnetic reference layer;
a magnetic recording layer provided on the tunnel barrier layer and having a perpendicular magnetic anisotropy and a variable magnetization direction;
a nonmagnetic nano-current-crowding channel (NCC) structure provided on the magnetic recording layer;
a protective cap layer provided on the NCC structure; and
a hard mask layer provided on the protective cap layer;
wherein said tunnel barrier layer has a first resistance-area product, said NCC structure comprises an insulating medium throughout said NCC thickness, and a conductive medium throughout said NCC thickness, the insulating medium comprising an insulating oxide or nitride material and having a second resistance-area product, the second resistance-area product being larger than the first resistance-area product, the conductive medium comprising a metal or metal alloy or metal nitride material and being an electrically conductive path between the magnetic recording layer and the protective cap layer, said magnetic recording layer has a sufficiently small sheet resistance so that an electric current crowding occurs in said magnetic recording layer while the current density across said tunnel barrier layer is substantially uniform when a voltage is applied to said magnetoresistive element.

20. A magnetoresistive element comprising:
a bottom electrode provided on a substrate;
a sidewall-current-channel (SCC) structure provided on the bottom electrode, wherein the SCC structure comprises an insulating medium in a central region of the SCC structure, and a conductive medium being a vertical sidewall of the SCC structure and surrounding the insulating medium;
a perpendicular anisotropy enhancement layer provided on the insulating medium;
a magnetic recording layer provided on the perpendicular anisotropy enhancement layer and having a perpendicular magnetic anisotropy and a variable magnetization direction;
a tunnel barrier layer provided on the magnetic recording layer;
a magnetic reference layer provided on the tunnel barrier layer and having a perpendicular magnetic anisotropy and having an invariable magnetization direction;
a protective cap layer provided on the insulating medium; and
a hard mask layer provided on the protective cap layer;
wherein the tunnel barrier layer has a first resistance-area product (RA₁), the insulating medium comprises an insulating oxide or nitride material and has a second resistance-area product (RA₂), the second resistance-area product (RA₂) is higher than the first resistance-area product (RA₁), the conductive medium comprises a conductive material making electrical connection between the magnetic recording layer and the bottom electrode layer.
